(19) United States
(12) Patent Application Publication
(10) Pub. No.: US 2026/0337786 A1
(43) Pub. Date: Oct. 29, 2026

(54) ETCHANT COMPOSITION

(71) Applicant: Kao Corporation, Tokyo (JP)

(72) Inventor: Yohei UCHIDA, Wakayama (JP)

(73) Assignee: Kao Corporation, Tokyo (JP)

(21) Appl. No.: 19/109,034

(22) PCT Filed: Sep. 5, 2023
(86) PCT No.: PCT/JP2023/032305

§ 371 Date: Mar. 5, 2025

(30) Foreign Application Priority Data
Sep. 6, 2022 (JP) 2022-141490

(51) Int. Cl. C23F 11/14; C23F 11/18; H10P 50/66

(52) U.S. Cl. CPC C23F 11/141; C23F 11/181; C23F 11/184; H10P 50/667

(57) ABSTRACT

In one aspect, provided is an etchant composition with high storage stability.

An aspect of the present disclosure relates to an etchant composition for etching of a layer to be etched that contains at least one metal. The etchant composition contains a nitric acid, a polyamine with a number average molecular weight of 300 or more, a nitrogen-containing basic compound with a molecular weight of less than 300, and water.

### TECHNICAL FIELD

The present disclosure relates to an etchant composition and an etching method using the etchant composition.

### BACKGROUND ART

The manufacturing process of a semiconductor device includes a step of etching a layer to be etched to form a predetermined pattern. The layer to be etched contains at least one metal selected from, e.g., tungsten, tantalum, zirconium, hafnium, molybdenum, niobium, ruthenium, osmium, rhenium, rhodium, copper, nickel, cobalt, titanium, titanium nitride, alumina, aluminum, or iridium.

In the field of semiconductor, wiring has been required to be finer and more complicated due to a high level of integration in recent years. There is also a growing demand for patterning technology and etchants, and a variety of etching methods and etchants have been proposed.

For example, JP 2012-49535 A (Patent Document 1) proposes a method for simultaneously etching a multilayer film such as a Cu/Mo laminated metal film with an etchant composition that contains 50 to 80% by mass of phosphoric acid, 0.5 to 10% by mass of nitric acid, 5 to 30% by mass of acetic acid, and 0.01 to 5% by mass of imidazole.

JP 2015-144230 A (Patent Document 2) proposes a method for etching a titanium-containing layer and a silicon containing layer with an etchant that contains a nitric acid, a fluorine-containing compound, and a nitrogen-containing organic compound A or a phosphorus-containing compound B, in which the nitrogen-containing organic compound A has a plurality of repeating units including nitrogen atoms.

JP 2013-237873 A (Patent Document 3) proposes an etchant that contains a phosphoric acid, a nitric acid, and a polyalkylene polyamine including three or more amino groups in one molecule. The etchant is used for etching a metal film having at least one layer of a metal thin film of molybdenum or a molybdenum alloy.

JP 2022-2324 A (Patent Document 4) proposes an etchant that is suitable for both tungsten-containing metals and TiN-containing materials, and that contains at least one or two components selected from water, an oxidizer, a fluorine-containing etching compound, an organic solvent, a chelating agent, a corrosion inhibitor, or a surfactant.

### DISCLOSURE OF THE INVENTION

An aspect of the present disclosure relates to an etchant composition for etching of a layer to be etched that contains at least one metal. The etchant composition contains a nitric acid, a polyamine with a number average molecular weight of 300 or more, a nitrogen-containing basic compound with a molecular weight of less than 300, and water.

An aspect of the present disclosure relates to an etching method that includes etching a layer to be etched that contains at least one metal with the etchant composition of the present disclosure.

### DESCRIPTION OF THE INVENTION

An etchant is generally a mixed acid aqueous solution (strong acid aqueous solution) containing a phosphoric acid, a nitric acid, and an acetic acid. Patent Document 2 proposes adding the nitrogen-containing organic compound such as polyethyleneimine as an agent to inhibit etching and improve etching selectivity. However, the addition of polyethyleneimine or the like to the mixed acid aqueous solution may cause turbidity and degrade the storage stability of the etchant. In particular, the solution tends to be turbid when stored at a low temperature (e.g., 10 °C or less).

With the foregoing in mind, in one aspect, the present disclosure provides an etchant composition with high storage stability, and an etching method using the etchant composition.

In one aspect, the present disclosure can provide the etchant composition with high storage stability.

The present inventors intensively studied and have found that an etchant containing a nitric acid, a polyamine with a number average molecular weight of 300 or more, and a nitrogen containing basic compound with a molecular weight of less than 300 is able to improve the storage stability, particularly at a low temperature (10 °C or less).

In one aspect, the present disclosure relates to an etchant composition for etching of a layer to be etched that contains at least one metal (also referred to as an “etchant composition of the present disclosure” in the following). The etchant composition of the present disclosure contains a nitric acid, a polyamine with a number average molecular weight of 300 or more, a nitrogen containing basic compound with a molecular weight of less than 300, and water.

The details of the mechanism of the effects of the present disclosure are not fully clear, but can be assumed as follows.

The polyamine has two or more amino groups in a molecule, and all of the amino groups may react with the nitric acid to form salts in water. The salts of the amino groups and the nitric acid are not very soluble in water. Therefore, the larger the number of the amino groups forming salts with the nitric acid, the lower the solubility of the salts in the solution and the more likely the solution will be turbid, particularly at a low temperature (e.g., 10 °C or less). The present disclosure uses the polyamine with a number average molecular weight of 300 or more in combination with the nitrogen-containing basic compound with a molecular weight of less than 300. As a result of this, since the nitrogen-containing basic compound reacts with the nitric acid to form a salt, the amount of nitrate ions is reduced, which in turn reduces the number of amino groups in a molecule of the polyamine that would form salts with the nitric acid. Thus, the amount of salts of the amino groups in a molecule of the polyamine and the nitric acid is reduced, and the solution is not likely to be turbid even when stored at a low temperature (e.g., 10 °C or less), so that the storage stability can be improved.

The etchant composition of the present disclosure has stable composition and comes into uniform contact with the layer to be etched, which may result in uniform etching.

However, the present disclosure should not be interpreted solely by the above mechanism.

### [Nitric Acid]

The blending amount of the nitric acid in the etchant composition of the present disclosure is preferably 0.5% by mass or more, more preferably 1% by mass or more, and further preferably 1.5% by mass or more from the viewpoint of improving the etching rate. Furthermore, the blending amount of the nitric acid is preferably 20% by mass or less, more preferably 10% by mass or less, and further preferably 8% by mass or less from the viewpoint of improving the storage stability. More specifically, the blending amount of the nitric acid is preferably 0.5% by mass or more and 20% by mass or less, more preferably 1% by mass or more and 10% by mass or less, and further preferably 1.5% by mass or more and 8% by mass or less.

[Polyamine with Number Average Molecular Weight of 300 or More]

In one or more embodiments, the polyamine with a number average molecular weight of 300 or more contained in the etchant composition of the present disclosure may be a compound having two or more amino groups in a molecule. In one or more embodiments, from the viewpoint of etching inhibition, examples of the polyamine include polyalkyleneimine and a polymer with a constitutional unit derived from a compound having amino groups and an ethylenically unsaturated double bond. The polyalkyleneimine may be, e.g., polyethyleneimine (PEI) and is preferably branched polyethyleneimine. The polymer with a constitutional unit derived from a compound having amino groups and an ethylenically unsaturated double bond may be, e.g., a diallylamine copolymer, a diallylamine/sulfur dioxide copolymer, a diallyldimethylammonium chloride polymer, or a diallyldimethylammonium chloride/sulfur dioxide copolymer. Among them, polyalkyleneimine such as PEI is preferred from the viewpoint of etching inhibition. The polyamine with a number average molecular weight of 300 or more may be used alone or in combination of two or more.

In one or more embodiments, the number average molecular weight of the polyamine is 300 or more, preferably 600 or more, and more preferably 1,200 or more from the viewpoint of etching inhibition. Furthermore, the number average molecular weight of the polyamine is preferably 100,000 or less, more preferably 5,000 or less, and further preferably 3,000 or less from the viewpoint of improving the storage stability. More specifically, the number average molecular weight of the polyamine is preferably 300 or more and 100,000 or less, more preferably 600 or more and 5,000 or less, and further preferably 1,200 or more and 3,000 or less.

In the present disclosure, the number average molecular weight may be measured by gel permeation chromatography (GPC) under the following conditions.

### <GPC Conditions>

Sample solution: solution adjusted to a concentration of 0.1 wt %
Device/Detector: HLC-8320GPC (integrated GPC) manufactured by Tosoh Corporation
Column: α-M+α-M (manufactured by Tosoh Corporation)
Eluent: 0.15 mol/L Na₂SO₄, 1% CH₃COOH/water
Column temperature: 40 °C.
Flow rate: 1.0 ml/min
Injection volume of sample solution: 100 μL
Standard polymer: pullulan with a known molecular weight (P-5, P-50, P-200, and P-800 by Shodex)

The blending amount of the polyamine with a number average molecular weight of 300 or more in the etchant composition of the present disclosure is preferably 0.1% by mass or more, more preferably 0.2% by mass or more, and further preferably 0.4% by mass or more from the viewpoint of improving the storage stability. Furthermore, the blending amount of the polyamine is preferably 20% by mass or less, more preferably 10% by mass or less, and further preferably 5% by mass or less from the viewpoint of the permeability during filtration associated with the solution viscosity. More specifically, the blending amount of the polyamine is preferably 0.1% by mass or more and 20% by mass or less, more preferably 0.2% by mass or more and 10% by mass or less, and further preferably 0.4% by mass or more and 5% by mass or less. When the polyamine is a combination of two or more types, the blending amount of the polyamine is the total amount of the two or more types.

[Nitrogen-Containing Basic Compound with Molecular Weight of Less than 300]

In one or more embodiments, the molecular weight of the nitrogen-containing basic compound contained in the etchant composition of the present disclosure is less than 300, preferably 250 or less, and more preferably 200 or less from the viewpoint of improving the storage stability. Furthermore, the molecular weight of the nitrogen-containing basic compound is preferably 15 or more, more preferably 20 or more, and further preferably 30 or more from the viewpoint of uniform etching of the layer to be etched. More specifically, the molecular weight of the nitrogen containing basic compound is preferably 15 or more and less than 300, more preferably 20 or more and 250 or less, and further preferably 30 or more and 200 or less.

In one or more embodiments, the nitrogen containing basic compound is preferably at least one selected from the group consisting of ammonia, alkylamine, alkanolamine, alicyclic amine, aromatic amine, and polyalkylene polyamine, and more preferably at least one selected from the group consisting of ammonia, alicyclic amine, and polyalkylene polyamine from the viewpoint of improving the storage stability.

The alkylamine may be, e.g., ethylamine. The alkanolamine may be, e.g., 2-(2-aminoethylamino)ethanol. The alicyclic amine may be, e.g., N-(2-hydroxyethyl)piperazine or N-(2-aminoethyl)piperazine. The aromatic amine may be, e.g., benzotriazole, aminopyrazole, aminopyridine, aminopyrimidine, aminopyrazine, aminooxazole, or thiazoleamine. From the same viewpoint, the polyalkylene polyamine is preferably polyalkylene polyamine having 2 to 4 amino groups in a molecule, and more preferably at least one selected from the group consisting of alkylenediamine, dialkylenetriamine, and trialkylenetetramine. The alkylenediamine may be, e.g., ethylenediamine. The dialkylenetriamine may be, e.g., diethylenetriamine. The trialkylenetetramine may be, e.g., triethylenetetramine.

The nitrogen-containing basic compound with a molecular weight of less than 300 may be used alone or in combination of two or more.

The blending amount of the nitrogen-containing basic compound with a molecular weight of less than 300 in the etchant composition of the present disclosure is preferably 0.4% by mass or more, more preferably 0.8% by mass or more, and further preferably 1.2% by mass or more from the viewpoint of improving the storage stability. Furthermore, the blending amount of the nitrogen-containing basic compound is preferably 20% by mass or less, more preferably 15% by mass or less, and further preferably 10% by mass or less from the viewpoint of the permeability during filtration associated with the solution viscosity. More specifically, the blending amount of the nitrogen-containing basic compound is preferably 0.4% by mass or more and 20% by mass or less, more preferably 0.8% by mass or more and 15% by mass or less, and further preferably 1.2% by mass or more and 10% by mass or less. When the nitrogen-containing basic compound is a combination of two or more types, the blending amount of the nitrogen containing basic compound is the total amount of the two or more types.

In the present disclosure, it is preferable that a, b, and c satisfy (a−c)⁴/b≤600, where a represents the blending amount (% by mass) of the nitric acid, b represents the blending amount (% by mass) of the polyamine with a number average molecular weight of 300 or more, and c represents the blending amount (% by mass) of the nitrogen-containing basic compound with a molecular weight of less than 300. In one or more embodiments, a and c satisfy a<c, a=c, or a>c. In this case, a, b, and c each indicate mass or percent by mass (the same applies hereinafter).

The value (a−c)⁴/b is preferably 600 or less, more preferably 550 or less, even more preferably 500 or less, and further preferably 400 or less from the viewpoint of improving the storage stability and also improving the storage stability at 10 °C or less. Furthermore, the value (a−c)⁴/b is preferably 0.01 or more, more preferably 0.1 or more, and further preferably 0.5 or more, 50 or more, 100 or more, 200 or more, or 300 or more from the viewpoint of uniform etching of the layer to be etched.

From the same viewpoint, the value (a−c)⁴/b is preferably 0.01 or more and 600 or less, more preferably 0.1 or more and 600 or less, even more preferably 0.5 or more and 600 or less, still more preferably 50 or more and 600 or less, yet more preferably 100 or more and 600 or less, further preferably 200 or more and 600 or less, even further preferably 300 or more and 600 or less, still further preferably 300 or more and 550 or less, and yet further preferably 300 or more and 500 or less.

The following is an explanation of the reason why the value (a−c)⁴/b is preferably 600 or less.

As described above, the polyamine has two or more amino groups in a molecule, and all of the amino groups may react with the nitric acid to form salts in water. The number of amino groups in a molecule of the polyamine that would form salts with the nitric acid depends on the amount of nitrate ions and the amount of ammonium ions contained in the etchant composition. As the blending amount of the polyamine increases, the amount of nitrate ions decreases relative to the amount of ammonium ions. This reduces the number of amino groups in a molecule of the polyamine that would form salts with the nitric acid. If the blending amount of the nitric acid is increased, the amount of nitrate ions in the etchant composition is dramatically increased due to a significant decrease in pH as well as an increase in the amount of the nitric acid. Consequently, the number of amino groups in a molecule of the polyamine that would form salts with the nitric acid will be greatly increased. On the other hand, when the polyamine with a number average molecular weight of 300 or more coexists with the nitrogen-containing basic compound with a molecular weight of less than 300, since the nitrogen containing basic compound reacts with the nitric acid to form a salt, the amount of nitrate ions is reduced, which in turn reduces the number of amino groups in a molecule of the polyamine that would form salts with the nitric acid. The amine/nitric acid salts are not very soluble in water. Therefore, when the water concentration is low, the larger the number of the amino groups forming salts with the nitric acid, the lower the solubility of the salts in the solution and the more likely the solution will be turbid, particularly at a low temperature (e.g., 10 °C or less). The amount of salts formed depends on the amount of nitrate ions and the amount of ammonium ions, as described above, and is significantly affected by the amount of the nitric acid and the amount of the nitrogen-containing basic compound.

The present inventors confirmed in detail the effect of the ratio of the amount of nitrate ions to the amount of ammonium ions, and revealed that the solution is less likely to be turbid even when stored at a low temperature (e.g., 10 °C or less), and the storage stability can be further improved, provided that a, b, and c satisfy (a−c)⁴/b≤600, where a represents the blending amount (% by mass) of the nitric acid, b represents the blending amount (% by mass) of the polyamine with a number average molecular weight of 300 or more, and c represents the blending amount (% by mass) of the nitrogen-containing basic compound with a molecular weight of less than 300.

Thus, the etchant composition has more stable composition and comes into more uniform contact with the layer to be etched, which may result in etching with further reduced etching nonuniformity.

[Acid Other than Nitric Acid]

The etchant composition of the present disclosure may further contain an acid other than the nitric acid from the viewpoint of uniform etching of the layer to be etched. The acid other than the nitric acid may be used alone or in combination of two or more.

The acid other than the nitric acid may be at least one selected from the group consisting of phosphoric acid, hydrochloric acid, sulfuric acid, and organic acid. Examples of the organic acid include at least one selected from the group consisting of formic acid, acetic acid, methoxyacetic acid, ethoxyacetic acid, propionic acid, butyric acid, oxalic acid, malonic acid, succinic acid, glutaric acid, adipic acid, pimelic acid, maleic acid, fumaric acid, phthalic acid, trimellitic acid, hydroxyacetic acid, lactic acid, salicylic acid, malic acid, tartaric acid, citric acid, aspartic acid, and glutamic acid. Among them, the acid other than the nitric acid is preferably at least one selected from the group consisting of phosphoric acid, acetic acid, methoxyacetic acid, and ethoxyacetic acid, more preferably at least one selected from the group consisting of phosphoric acid and acetic acid, and further preferably a combination of phosphoric acid and acetic acid from the viewpoint of uniform etching of the layer to be etched.

When the etchant of the present disclosure further contains an acid other than the nitric acid, the blending amount of the acid other than the nitric acid in the etchant of the present disclosure is preferably 65% by mass or more, more preferably 70% by mass or more, and further preferably 75% by mass or more from the viewpoint of uniform etching of the layer to be etched. From the same viewpoint, the blending amount of the acid other than the nitric acid is preferably 98% by mass or less, more preferably 95% by mass or less, and further preferably 90% by mass or less. More specifically, the blending amount of the acid other than the nitric acid is preferably 65% by mass or more and 98% by mass or less, more preferably 70% by mass or more and 95% by mass or less, and further preferably 75% by mass or more and 90% by mass or less. When the acid other than the nitric acid is a combination of two or more types, the blending amount of the acid other than the nitric acid is the total amount of the two or more types.

When the acid other than the nitric acid is a combination of phosphoric acid and acetic acid, the blending amount of the phosphoric acid in the etchant composition of the present disclosure is preferably 50% by mass or more and 95% by mass or less, more preferably 55% by mass or more and 93% by mass or less, and further preferably 60% by mass or more and 90% by mass or less from the viewpoint of uniform etching of the layer to be etched. From the same viewpoint, the blending amount of the acetic acid in the etchant composition of the present disclosure is preferably 2% by mass or more and 80% by mass or less, more preferably 3% by mass or more and 60% by mass or less, and further preferably 5% by mass or more and 30% by mass or less.

### [Water]

In one or more embodiments, the etchant composition of the present disclosure contains water. The water contained in the etchant composition may be, e.g., distilled water, ion-exchanged water, pure water, or ultrapure water.

The blending amount of water in the etchant composition of the present disclosure is preferably 2% by mass or more, more preferably 5% by mass or more, and further preferably 7% by mass or more from the viewpoint of improving the storage stability. Furthermore, the blending amount of water is preferably 30% by mass or less, more preferably 25% by mass or less, and further preferably 20% by mass or less from the viewpoint of uniform etching of the layer to be etched. More specifically, the blending amount of water is preferably 2% by mass or more and 30% by mass or less, more preferably 5% by mass or more and 25% by mass or less, and further preferably 7% by mass or more and 20% by mass or less.

### [Other Components]

The etchant composition of the present disclosure may further contain other components to the extent that they do not interfere with the effects of the present disclosure. The other components include, e.g., a chelating agent, a surface-active agent, a solubilizing agent, an antiseptic, an anticorrosive, a bactericide, an antibacterial agent, and an antioxidant.

In one or more embodiments, the etchant composition of the present disclosure may contain substantially no imidazole. The blending amount of the imidazole in the etchant composition of the present disclosure is preferably less than 0.01% by mass, more preferably 0.001% by mass or less, and further preferably 0% by mass (i.e., no imidazole is contained).

In one or more embodiments, the etchant composition of the present disclosure may contain substantially no fluorine-containing compound. The blending amount of the fluorine-containing compound in the etchant composition of the present disclosure is preferably less than 0.001% by mass, more preferably 0.0001% by mass or less, and further preferably 0% by mass (i.e., no fluorine-containing compound is contained).

In one or more embodiments, the etchant composition of the present disclosure may or may not contain hydrogen peroxide.

In one or more embodiments, the etchant composition of the present disclosure is not turbid at a temperature of preferably 10 °C or more, more preferably 5 °C or more, even more preferably 1 °C or more, still more preferably 0.5 °C or more, and further preferably 0 °C or more. The presence or absence of turbidity can be confirmed by a method as described in Examples.

### [Production Method of Etchant Composition]

In one aspect, the etchant composition of the present disclosure can be produced by blending a nitric acid, a polyamine with a number average molecular weight of 300 or more, a nitrogen-containing basic compound with a molecular weight of less than 300, and water, and the optional components as desired, with a known method. Thus, an aspect of the present disclosure relates to a method for producing an etchant composition (also referred to as a “production method of an etchant of the present disclosure” in the following). The production method of an etchant of the present disclosure includes blending at least a nitric acid, a polyamine with a number average molecular weight of 300 or more, a nitrogen-containing basic compound with a molecular weight of less than 300, and water.

In the context of the present disclosure, in one or more embodiments, the process of “blending at least a nitric acid, a polyamine with a number average molecular weight of 300 or more, a nitrogen-containing basic compound with a molecular weight of less than 300, and water” includes mixing the nitric acid, the polyamine with a number average molecular weight of 300 or more, the nitrogen-containing basic compound with a molecular weight of less than 300, and water, and the optional components as needed, simultaneously or in sequence. They can be mixed in any order. The blending can be performed by using, e.g., a propeller agitator, liquid circulation stirring with a pump, or mixers such as a homomixer, a homogenizer, an ultrasonic disperser, and a wet ball mill.

The preferred blending amount of each component in the production method of an etchant of the present disclosure may be the same as the preferred blending amount of each component in the etchant composition of the present disclosure, as described above.

In the context of the present disclosure, in one or more embodiments, the “blending amount of each component in the etchant composition” means the amount of each component in the etchant composition that is to be used in the etching process, i.e., the amount of each component in the etchant composition at the time the etchant composition starts to be used in an etching treatment (at the time of use).

In one or more embodiments, the blending amount of each component in the etchant composition of the present disclosure may be considered as the content of each component in the etchant composition. However, the blending amount of each component may differ from the content of each component depending on the effect of neutralization.

An embodiment of the etchant composition of the present disclosure may be either a so-called one-part or two-part etchant composition. The one part etchant composition is supplied to the market with all the components being mixed together. On the other hand, the components of the two-part etchant composition are mixed at the time of use. An embodiment of the two-part etchant composition may include a solution (first solution) containing a nitric acid and a solution (second solution) containing a polyamine with a number average molecular weight of 300 or more and a nitrogen-containing basic compound with a molecular weight of less than 300. The first solution and the second solution may be mixed at the time of use. After the first solution and the second solution are mixed together, the mixed solution may be diluted with water or an acid aqueous solution as needed. The first solution or the second solution may contain the whole or part of the amount of water used for the preparation of the etchant. Each of the first solution and the second solution may contain the above optional components as needed.

The pH of the etchant composition of the present disclosure is preferably 1 or less, more preferably 0 or less, even more preferably less than 0, and further preferably about—1 from the viewpoint of uniform etching of the layer to be etched. The pH of the etchant composition may be preferably—5 or more, and more preferably—3 or more. In the present disclosure, the pH of the etchant composition is a value at a temperature of 25 °C and can be measured with a pH meter. Specifically, the pH of the etchant composition can be measured by a method as described in Examples.

The etchant composition of the present disclosure may be concentrated so as not to impair the stability, and stored and supplied in the concentrated state. This can reduce the production and transportation costs. If necessary, the concentrated solution may be appropriately diluted with water or an acid aqueous solution and used in the etching process. The dilution factor may be, e.g., 5 to 100.

### [Kit]

In another aspect, the present disclosure relates to a kit for producing the etchant composition of the present disclosure (also referred to as a “kit of the present disclosure” in the following).

The kit of the present disclosure may be, e.g., a kit (two-part etchant) that includes a solution (first solution) containing a nitric acid and a solution (second solution) containing a polyamine with a number average molecular weight of 300 or more and a nitrogen-containing basic compound with a molecular weight of less than 300 so that the two solutions are not mixed with each other. The first solution and the second solution are mixed at the time of use. After the first solution and the second solution are mixed together, the mixed solution may be diluted with water or an acid aqueous solution as needed. The first solution or the second solution may contain the whole or part of the amount of water used for the preparation of the etchant. Each of the first solution and the second solution may contain the above optional components as needed. The kit of the present disclosure enables the preparation of an etchant with high storage stability.

### [Layer to be Etched]

In one or more embodiments, the layer to be etched with the etchant composition of the present disclosure contains at least one metal. Any metal can be used as long as the effects of the present disclosure are obtained. For example, the metal may be at least one selected from the group consisting of tungsten, tantalum, zirconium, hafnium, molybdenum, niobium, ruthenium, osmium, rhenium, rhodium, copper, nickel, cobalt, titanium, titanium nitride, alumina, aluminum, and iridium. In one or more embodiments, the etchant composition of the present disclosure is preferably used to etch the layer to be etched that contains at least one metal selected from the group consisting of tungsten, molybdenum, niobium, tantalum, and zirconium. Further, in one or more embodiments, the etchant composition is preferably used to etch a tungsten film or a molybdenum film. Thus, in one or more embodiments, the layer to be etched may be a tungsten film or a molybdenum film.

### [Etching Method]

In one aspect, the present disclosure relates to an etching method (also referred to as an “etching method of the present disclosure” in the following). The etching method of the present disclosure includes etching a layer to be etched that contains at least one metal with the etchant composition of the present disclosure (also referred to as an “etching process of the present disclosure” in the following). In one or more embodiments, the use of the etching method of the present disclosure along with the etchant with high storage stability can improve the productivity of a semiconductor substrate.

Examples of the etching treatment in the etching process of the present disclosure include immersion etching and single wafer etching.

In one or more embodiments, when the layer to be etched is a tungsten film, the temperature (etching temperature) of the etchant composition in the etching process of the present disclosure is preferably 0 °C or more, more preferably 50 °C or more, and further preferably 70 °C or more and is also preferably 150 °C or less, more preferably 130 °C or less, and further preferably 110 °C or less from the viewpoint of reducing etching nonuniformity. More specifically, in one or more embodiments, when the layer to be etched is a tungsten film, the etching temperature is preferably 0 °C or more and 150 °C or less, more preferably 50 °C or more and 130 °C or less, and further preferably 70 °C or more and 110 °C or less.

In one or more embodiments, when the layer to be etched is a molybdenum film, the temperature (etching temperature) of the etchant composition in the etching process of the present disclosure is preferably 0 °C or more, more preferably 15 °C or more, and further preferably 20 °C or more and is also preferably 80 °C or less, more preferably 65 °C or less, and further preferably 50 °C or less from the viewpoint of reducing etching nonuniformity. More specifically, in one or more embodiments, when the layer to be etched is a molybdenum film, the etching temperature is preferably 0 °C or more and 80 °C or less, more preferably 15 °C or more and 65 °C or less, and further preferably 20 °C or more and 50 °C or less.

In one or more embodiments, when the layer to be etched is a nickel film, the temperature (etching temperature) of the etchant composition in the etching process of the present disclosure is preferably 0 °C or more, more preferably 15 °C or more, and further preferably 30 °C or more and is also preferably 80 °C or less, more preferably 65 °C or less, and further preferably 50 °C or less from the viewpoint of reducing etching nonuniformity. More specifically, in one or more embodiments, when the layer to be etched is a nickel film, the etching temperature is preferably 0 °C or more and 80 °C or less, more preferably 15 °C or more and 65 °C or less, and further preferably 30 °C or more and 50 °C or less.

In one or more embodiments, when the layer to be etched is a cobalt film, the temperature (etching temperature) of the etchant composition in the etching process of the present disclosure is preferably 0 °C or more, more preferably 15 °C or more, and further preferably 30 °C or more and is also preferably 80 °C or less, more preferably 65 °C or less, and further preferably 50 °C or less from the viewpoint of reducing etching nonuniformity. More specifically, in one or more embodiments, when the layer to be etched is a cobalt film, the etching temperature is preferably 0 °C or more and 80 °C or less, more preferably 15 °C or more and 65 °C or less, and further preferably 30 °C or more and 50 °C or less.

In one or more embodiments, when the layer to be etched is a titanium film, the temperature (etching temperature) of the etchant composition in the etching process of the present disclosure is preferably 0 °C or more, more preferably 50 °C or more, and further preferably 70 °C or more and is also preferably 150 °C or less, more preferably 130 °C or less, and further preferably 110 °C or less from the viewpoint of reducing etching nonuniformity. More specifically, in one or more embodiments, when the layer to be etched is a titanium film, the etching temperature is preferably 0 °C or more and 150 °C or less, more preferably 50 °C or more and 130 °C or less, and further preferably 70 °C or more and 110 °C or less.

In one or more embodiments, when the layer to be etched is a copper film, the temperature (etching temperature) of the etchant composition in the etching process of the present disclosure is preferably 0 °C or more, more preferably 15 °C or more, and further preferably 30 °C or more and is also preferably 80 °C or less, more preferably 65 °C or less, and further preferably 50 °C or less from the viewpoint of reducing etching nonuniformity. More specifically, in one or more embodiments, when the layer to be etched is a copper film, the etching temperature is preferably 0 °C or more and 80 °C or less, more preferably 15 °C or more and 65 °C or less, and further preferably 30 °C or more and 50 °C or less.

In the etching process of the present disclosure, the etching time may be set to, e.g., 1 minute or more and 180 minutes or less.

In one or more embodiments, the etching method of the present disclosure may include storing, retaining, or transporting the etchant composition of the present disclosure at a temperature of 10 °C or less.

In one or more embodiments, the etchant composition and the etching method of the present disclosure can be used to etch metals in the manufacturing process of electronic devices, particularly semiconductor wafers.

In one or more embodiments, the etchant composition and the etching method of the present disclosure can be suitably used for the production of semiconductor wafers. This can improve not only etching nonuniformity, but also productivity and yield.

In one or more embodiments, the etchant composition and the etching method of the present disclosure can be used to etch electrodes in the manufacturing process of electronic devices, particularly semiconductor memories such as nonvolatile memories including NAND flash memories.

In one or more embodiments, the etchant composition and the etching method of the present disclosure can be suitably used for the production of three-dimensional structure patterns. This can provide sophisticated devices such as large-capacity memories.

The etchant composition and the etching method of the present disclosure can be used for the etching method as disclosed in, e.g., JP 2020-145412 A.

### EXAMPLES

Hereinafter, the present disclosure will be described in detail by way of examples. However, the present disclosure is not limited to the following examples.

### 1. Preparation of Etchant (Examples 1 to 6, Comparative Example 1)

Etchants (pH: −1) of Examples 1 to 6 and Comparative Example 1 were prepared by blending a nitric acid, acids other than the nitric acid (phosphoric acid and acetic acid), a polyamine, a nitrogen-containing basic compound, and water, as shown in Table 1.

Table 1 shows the blending amount (% by mass, active part) of each component in each of the etchants thus prepared. In Table 1, the blending amount of water also includes the amount of water contained in, e.g., the acid aqueous solution.

The etchants were prepared by using the following components.
Nitric acid [concentration: 70%, manufactured by FUJIFILM Wako Pure Chemical Corporation]
Phosphoric acid [concentration: 85%, manufactured by RIN KAGAKU KOGYO CO., LTD.]
Acetic acid [concentration: 100%, manufactured by FUJIFILM Wako Pure Chemical Corporation]
PEI (polyethyleneimine) [number average molecular weight: 1,800, “EPOMIN SP-018” manufactured by NIPPON SHOKUBAI CO., LTD.]
Ethylenediamine [molecular weight: 60.1%, manufactured by FUJIFILM Wako Pure Chemical Corporation]
NH₃ (ammonia) [molecular weight: 17.03, concentration: 28%, manufactured by KISHIDA CHEMICAL CO., LTD.]
Triethylenetetramine [molecular weight: 146.23, manufactured by FUJIFILM Wako Pure Chemical Corporation]
Water [ultrapure water produced by using a continuous pure water production system (PURECONTI PC-2000VRL) and a subsystem (MAKUACE KC-05H), both manufactured by Kurita Water Industries Ltd.]

### 2. Method for Measuring Each Parameter

### [pH of Etchant]

The pH value of each etchant at 25 °C was measured with a pH meter (manufactured by DKK-TOA CORPORATION). Specifically, the pH value was obtained 1 minute after the electrode of the pH meter was immersed in the etchant.

### 3. Evaluation of Etchant

### [Presence or Absence of Turbidity (Storage Stability)]

Immediately after the preparation of each etchant composition, 20 ml of the etchant composition was placed in a sample bottle and allowed to stand still at 1 °C to visually observe the presence or absence of turbidity at regular time intervals. The etchant composition that did not become turbid even after standing still for 48 hours or more was rated A. The etchant composition that became turbid after standing still for more than 24 hours and less than 48 hours was rated B. The etchant composition that became turbid after standing still for 24 hours or less was rated C. Table 1 shows the results.

### [Evaluation of Etching Nonuniformity of Molybdenum Plate]

The etchants (Examples 1 to 6 and Comparative Example 1) that had been prepared with their respective compositions were stored at 1 °C for 1 week. Then, a molybdenum plate of 2 cm long, 2 cm wide, and 0.1 mm thick was weighed in advance and immersed in each of the etchants. The molybdenum plate was etched at 40 °C for 30 minutes. After the molybdenum plate was washed with water, the surface of the molybdenum plate was observed again with a 3D profile laser microscope VK-9710 (150×lens magnification) manufactured by KEYENCE CORPORATION. The resulting micrographs were analyzed in a surface-roughness mode of this microscope, and the profile irregularity, which is an indicator of etching nonuniformity, was determined by the following formula. Table 1 shows the results. The results confirm that the smaller the value of the profile irregularity, the more reduced the etching nonuniformity.

Profile irregularity (%)=surface roughness after etching/surface roughness before etching×100

TABLE 1

| | Composition | | | | | | | | | | |
|---|---|---|---|---|---|---|---|---|---|---|---|
| | | | | Polyamine | | | | | | Evaluation | |
| | | Acid other than | | PEI (number | | | | | | | Evaluation |
| | | nitric acid | | average | | | | | | Storage | of etching |
| | Nitric | Phosphoric | Acetic | molecular | Nitrogen-containing | | | | | stability | non- |
| | acid | acid | acid | weight: 1800) | basic compound | | | Water | | at low | uniformity |
| | Blending | Blending | Blending | Blending | | | Blending | Blending | | temper- | (profile |
| | amount a | amount | amount | amount b | | Molecular | amount c | amount | (a − | ature | irregularity, |
| | (mass %) | (mass %) | (mass %) | (mass %) | Type | weight | (mass %) | (mass %) | c)⁴/b | (1 °C) | %) |
| Comp. | 6 | 60 | 15 | 1 | — | — | — | 18 | 1296.0 | C | 320 |
| Ex. 1 | | | | | | | | | | | |
| Ex. 1 | 6 | 60 | 13.5 | 1 | ethylene- | 60.1 | 1.5 | 18 | 417.0 | A | 130 |
| | | | | | diamine | | | | | | |
| Ex. 2 | 6 | 60 | 13 | 1 | ethylene- | 60.1 | 2 | 18 | 313.0 | A | 120 |
| | | | | | diamine | | | | | | |
| Ex. 3 | 6 | 60 | 13.5 | 1 | NH₃ | 17.03 | 1.5 | 18 | 417.0 | A | 180 |
| Ex. 4 | 6 | 60 | 13.5 | 1 | triethylene- | 146.23 | 1.5 | 18 | 417.0 | A | 120 |
| | | | | | tetramine | | | | | | |
| Ex. 5 | 1.5 | 60 | 17.5 | 1 | ethylene- | 60.1 | 2 | 18 | 0.0625 | A | 150 |
| | | | | | diamine | | | | | | |
| Ex. 6 | 6 | 60 | 12 | 1 | triethylene- | 146.23 | 3 | 18 | 81.0 | A | 140 |
| | | | | | tetramine | | | | | | |

As shown in Table 1, the etchant compositions of Examples 1 to 6 have lower turbidity and higher storage stability even when stored at a low temperature, as compared to the etchant composition of Comparative Example 1 that does not contain a nitrogen containing basic compound with a molecular weight of less than 300.

Moreover, the value (a−c)⁴/b is 0.01 or more and 600 or less in Examples 1 to 6. This demonstrates that the etchant compositions of Examples 1 to 6 can better reduce etching nonuniformity.

### INDUSTRIAL APPLICABILITY

The etchant composition of the present disclosure has high storage stability and is useful in a method for producing a large-capacity semiconductor memory.

1. (canceled)

2. (canceled)

3. (canceled)

4. (canceled)

5. (canceled)

6. An etching method comprising:
etching a layer to be etched that contains molybdenum with an etchant composition that contains a nitric acid, a polyamine with a number average molecular weight of 300 or more, a nitrogen-containing basic compound with a molecular weight of less than 300, and water.

7. The etching method according to claim 6, wherein a, b, and c satisfy (a−c)⁴/b≤600, where a represents a blending amount (% by mass) of the nitric acid, b represents a blending amount (% by mass) of the polyamine with a number average molecular weight of 300 or more, and c represents a blending amount (% by mass) of the nitrogen-containing basic compound with a molecular weight of less than 300.

8. The etching method according to claim 6, wherein the etchant composition further contains an acid other than the nitric acid.

9. The etching method according to claim 8, wherein the acid other than the nitric acid is at least one selected from the group consisting of phosphoric acid, acetic acid, methoxyacetic acid, and ethoxyacetic acid.

10. The etching method according to claim 6, wherein the polyamine is at least one selected from the group consisting of polyalkyleneimine and a polymer with a constitutional unit derived from a compound having amino groups and an ethylenically unsaturated double bond.

11. The etching method according to claim 6, wherein the nitrogen-containing basic compound is at least one selected from the group consisting of ammonia, alkylamine, alkanolamine, alicyclic amine, aromatic amine, and polyalkylene polyamine.

12. The etching method according to claim 6, wherein the etching method is used to etch metal in a manufacturing process of a semiconductor wafer.

13. An etching method comprising:
etching a layer to be etched that contains molybdenum with an etchant composition that is provided by blending a nitric acid, a polyamine with a number average molecular weight of 300 or more, a nitrogen-containing basic compound with a molecular weight of less than 300, and water.

14. An etchant composition for etching of a layer to be etched that contains molybdenum,
the etchant composition comprising a nitric acid, a polyamine with a number average molecular weight of 300 or more, a nitrogen-containing basic compound with a molecular weight of less than 300, and water.

15. The etchant composition according to claim 14, wherein a, b, and c satisfy (a−c)⁴/b≥600, where a represents a blending amount (% by mass) of the nitric acid, b represents a blending amount (% by mass) of the polyamine with a number average molecular weight of 300 or more, and c represents a blending amount (% by mass) of the nitrogen-containing basic compound with a molecular weight of less than 300.
